(19) United States
(12) Patent Application Publication
(10) Pub. No.: US 2025/0183018 A1
(43) Pub. Date: Jun. 5, 2025

(54) PARAMETER ESTIMATION SYSTEM, PARAMETER ESTIMATION METHOD, STORAGE MEDIUM, AND SUBSTRATE PROCESSING APPARATUS

(71) Applicant: Tokyo Electron Limited, Tokyo (JP)

(72) Inventor: Wataru SUWA, Miyagi (JP)

(73) Assignee: Tokyo Electron Limited, Tokyo (JP)

(21) Appl. No.: 19/047,965

(22) Filed: Feb. 7, 2025

Related U.S. Application Data
(63) Continuation of application No. PCT/JP2023/026740, filed on Jul. 21, 2023.

(30) Foreign Application Priority Data
Aug. 9, 2022 (JP) 2022-127153

(51) Int. Cl. H01J 37/32

(52) U.S. Cl. CPC H01J 37/32926; H01J 37/32724; H01J 37/3288; H01J 2237/2007; H01J 2237/24585; H01J 2237/24592

(57) ABSTRACT

A parameter estimation system includes: an acquisition unit that acquires temperature time-series data obtained by measuring a temperature of a substrate placement stage provided in a substrate processing apparatus in a time-series manner when increasing the temperature of the substrate placement stage, the substrate processing apparatus including the substrate placement stage and a cooling base that adjusts the temperature of the substrate placement stage via a cooling layer; a model calculation unit that calculates a temperature transition of the substrate placement stage using a physical model; an error calculation unit that calculates an error between the acquired temperature time-series data and temperature transition data; and an estimation unit that estimates parameters in the physical model, including a value of heat input to the substrate placement stage and a value of thermal resistance of the cooling layer, based on the calculated error.

### CROSS-REFERENCE TO RELATED APPLICATIONS

This application is a continuation application of International Patent Application No. PCT/JP2023/026740, filed on Jul. 21, 2023, which claims priority from Japanese Patent Application No. 2022-127153, filed on Aug. 9, 2022, with the Japan Patent Office, the disclosures of each are incorporated herein in their entireties by reference.

### TECHNICAL FIELD

The present disclosure relates to a parameter estimation system, a parameter estimation method, a storage medium, and a substrate processing apparatus.

### BACKGROUND

Japanese Patent Laid-Open Publication No. 2008-85329 discloses a plasma processing apparatus having a function to measure the temperature of a substrate support by a sensor and adjust the temperature of the substrate support according to the measured value.

### SUMMARY

According to an embodiment of the present disclosure, a parameter estimation system includes: an acquisition unit that acquires temperature time-series data obtained by measuring a temperature of a substrate placement stage provided in a substrate processing apparatus in a time-series manner when increasing the temperature of the substrate placement stage, the substrate processing apparatus including the substrate placement stage and a cooling base that adjusts the temperature of the substrate placement stage via a cooling layer; a model calculation unit that calculates a temperature transition of the substrate placement stage using a physical model; an error calculation unit that calculates an error between the temperature time-series data acquired by the acquisition unit and temperature transition data obtained from the model calculation unit; and an estimation circuit that estimates parameters in the physical model, including a value of heat input to the substrate placement stage and a value of thermal resistance of the cooling layer, based on the error calculated by the error calculation unit.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a schematic view illustrating an example of a configuration of a plasma processing system.

FIG. 2 is a view illustrating a substrate temperature adjustment mechanism.

FIG. 3 is a graph illustrating a variation in temperature of an electrostatic chuck over time.

FIG. 4A is a graph illustrating a variation in temperature rise curve when a parameter is changed.

FIG. 4B is a graph illustrating a variation in temperature rise curve when a parameter is changed.

FIG. 5 is a graph illustrating an error distribution when parameters are changed.

FIG. 6 is a graph illustrating an error distribution in a diagonal direction.

FIG. 7 is a flowchart illustrating a procedure of processes performed by a control unit of the plasma processing system.

FIG. 8 is a flowchart illustrating a procedure of processes performed by a processing unit according to Embodiment 2.

FIG. 9 is a flowchart illustrating a procedure of processes performed by a processing unit according to Embodiment 3.

FIG. 10 is a flowchart illustrating a procedure of processes performed by a processing unit according to Embodiment 4.

FIG. 11 is a schematic view illustrating a configuration of an electrostatic chuck according to Embodiment 5.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, the present disclosure is described in detail based on the drawings illustrating embodiments thereof.

### Embodiment 1

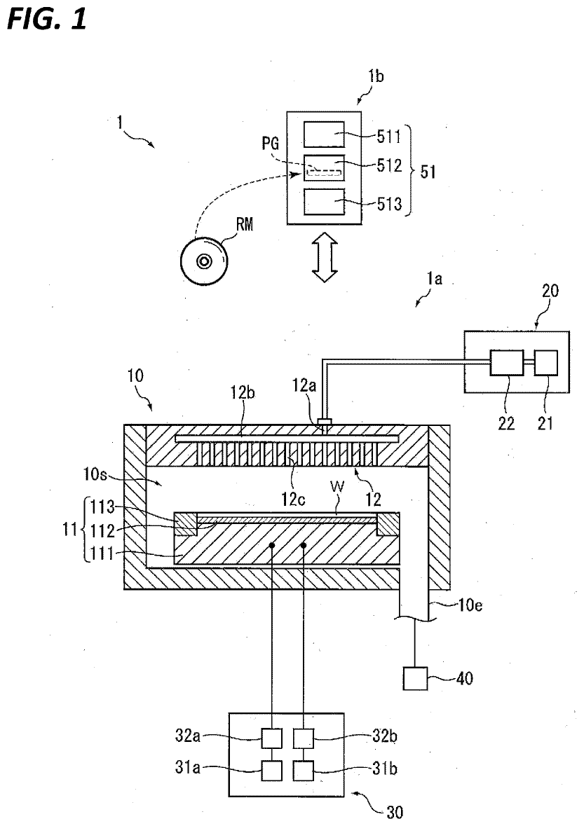

FIG. 1 is a schematic view illustrating an example of a configuration of a plasma processing system 1. In an embodiment, the plasma processing system 1 includes a plasma processing apparatus 1a and a control unit 1b. The plasma processing apparatus 1a includes a plasma processing chamber 10, a gas supply unit 20, a radio-frequency (RF) power supply unit 30, and an exhaust system 40. Further, the plasma processing apparatus 1a includes a support unit 11 and an upper electrode shower head 12. The support unit 11 is disposed in the lower region of a plasma processing space 10s inside the plasma processing chamber 10. The upper electrode shower head 12 is disposed above the support unit 11, and may serve as a portion of the ceiling of the plasma processing chamber 10.

The support unit 11 is configured to support a substrate W in the plasma processing space 10s. In an embodiment, the support unit 11 includes a lower electrode 111, an electrostatic chuck 112, and an edge ring 113. The electrostatic chuck 112 is disposed on the lower electrode 111, and is configured to support the substrate W on the upper surface thereof. The electrostatic chuck 112 is formed of ceramics. The edge ring 113 is disposed to surround the substrate W on the upper peripheral surface of the lower electrode 111. Although not illustrated, in an embodiment, the support unit 11 may include a temperature adjustment module configured to adjust at least one of the electrostatic chuck 112 and the substrate W to a target temperature. The temperature adjustment module may include a heater, a flow path, or a combination thereof. A temperature adjustment fluid such as a coolant or a heat transfer gas flows through the flow path.

The upper electrode shower head 12 is configured to supply one or more processing gases from the gas supply unit 20 to the plasma processing space 10s. In an embodiment, the upper electrode shower head 12 includes a gas inlet 12a, a gas diffusion chamber 12b, and a plurality of gas outlets 12c. The gas inlet 12a is in fluid communication with the gas supply unit 20 and the gas diffusion chamber 12b. The plurality of gas outlets 12c are in fluid communication with the gas diffusion chamber 12b and the plasma processing space 10s. In an embodiment, the upper electrode shower head 12 is configured to supply one or more processing gases from the gas inlet 12a to the plasma processing space 10s through the gas diffusion chamber 12b and the plurality of gas outlets 12c.

The gas supply unit 20 may include one or more gas sources 21 and one or more flow controllers 22. In an embodiment, the gas supply unit 20 is configured to supply one or more processing gases from each corresponding gas source 21 to the gas inlet 12a via each corresponding flow controller 22. Each flow controller 22 may include, for example, a mass flow controller or a pressure controlled-type flow controller. Further, the gas supply unit 20 may include one or more flow modulation devices that modulate or pulse the flow rate of one or more processing gases.

The RF power supply unit 30 is configured to supply an RF power, e.g., one or more RF signals, to one or more electrodes such as the lower electrode 111, the upper electrode shower head 12, or both the lower electrode 111 and the upper electrode shower head 12. As a result, a plasma is generated from one or more processing gases supplied to the plasma processing space 10s. Thus, the RF power supply unit 30 may function as at least a portion of a plasma generation unit configured to generate a plasma from one or more processing gases in the plasma processing chamber. In an embodiment, the RF power supply unit 30 includes two RF generation units 31a and 31b and two matching circuits 32a and 32b. In an embodiment, the RF power supply unit 30 is configured to supply a first RF signal from the first RF generation unit 31a to the lower electrode 111 via the first matching circuit 32a. For example, the first RF signal may have a frequency in the range of 27 MHz to 100 MHz.

In an embodiment, the RF power supply unit 30 is configured to supply a second RF signal from the second RF generation unit 31b to the lower electrode 111 via the second matching circuit 32b. For example, the second RF signal may have a frequency in the range of 400 kHz to 13.56 MHz. Alternatively, instead of the second RF generation unit 31b, a direct current (DC) pulse generation unit may be used.

Although not illustrated, other embodiments of the present disclosure may be conceived. For example, in an alternative embodiment, the RF power supply unit 30 may be configured to supply the first RF signal from an RF generation unit to the lower electrode 111, the second RF signal from another RF generation unit to the lower electrode 111, and a third RF signal from yet another RF generation unit to the lower electrode 111. In addition, in another alternative embodiment, a DC voltage may be applied to the upper electrode shower head 12.

In various embodiments, the amplitude of one or more RF signals (e.g., the first RF signal and the second RF signal) may be pulsed or modulated. The modulation of the amplitude may include pulsing the amplitude of the RF signal between ON and OFF states or between two or more different ON states.

The exhaust system 40 may be connected to an exhaust port 10e provided, for example, at the bottom of the plasma processing chamber 10. The exhaust system 40 may include a pressure valve and a vacuum pump. The vacuum pump may include a turbo molecular pump, a roughing pump, or a combination thereof.

In an embodiment, the control unit 1b processes computer-executable instructions that cause the plasma processing apparatus 1a to perform various processes described herein. The control unit 1b may be configured to control each component of the plasma processing apparatus 1a to perform the various processes described herein. In an embodiment, a portion of the control unit 1b or the entire control unit 1b may be included in the plasma processing apparatus 1a. The control unit 1b may include, for example, a computer 51. The computer 51 may include, for example, a processing unit (e.g., a central processing unit (CPU)) 511, a storage unit 512, and a communication interface 513. The processing unit 511 may be configured to perform various control operations based on programs stored in the storage unit 512. The storage unit 512 may include a random access memory (RAM), a read only memory (ROM), a hard disk drive (HDD), a solid state drive (SSD), or a combination thereof. The communication interface 513 may communicate with the plasma processing apparatus 1a via a communication line such as a local area network (LAN).

The storage unit 512 may store various computer programs to be executed by the processing unit 511. The computer program stored in the storage unit 512 includes, for example, a computer program PG for causing the processing unit 511 to execute an estimation process of estimating parameters used in a physical model for calculating a temperature transition of the electrostatic chuck 112 (substrate placement stage). The computer program PG is provided through a recording medium RM or a communication. The computer program PG may be a single computer program or a group of programs including a plurality of computer programs. Further, the computer program PG may use a portion of an existing library.

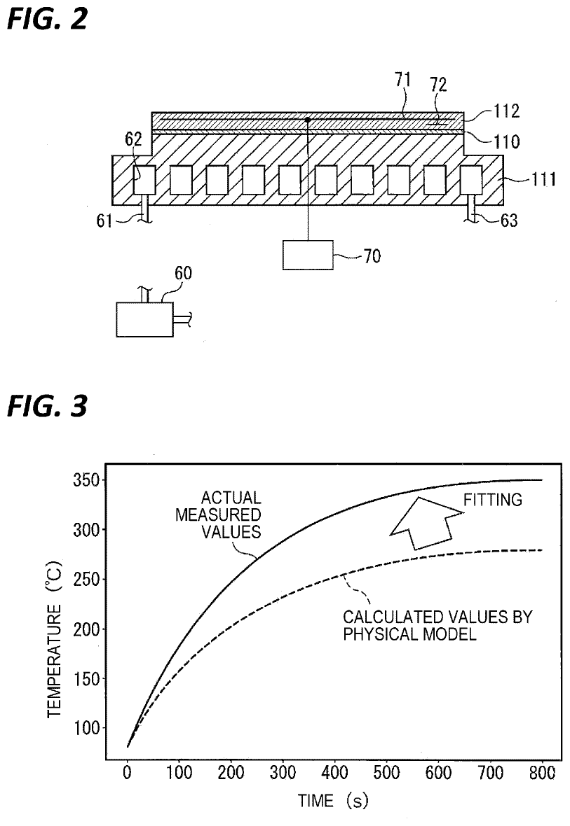

FIG. 2 is a view illustrating a substrate temperature adjustment mechanism. The support unit 11 of the plasma processing apparatus 1a includes the lower electrode 111 and the electrostatic chuck 112. In the present embodiment, the lower electrode 111 is configured to function as a cooling base that cools the electrostatic chuck 112. The electrostatic chuck 112 is provided as a substrate placement stage for placing the processing target substrate W thereon. The lower electrode 111 and the electrostatic chuck 112 are adhered to each other by an adhesive layer 110.

A coolant flow path 62 is formed inside the lower electrode 111. A coolant is supplied to the coolant flow path 62 from a chiller unit 60 provided outside the plasma processing chamber 10 through an inlet pipe 61. A suitable medium, such as brine, is used as the coolant. The coolant supplied to the coolant flow path 62 returns to the chiller unit 60 through an outlet pipe 63.

A heater 71 and a temperature sensor 72 are provided inside the electrostatic chuck 112. The heater 71 is connected to a heater power supply 70 provided outside the plasma processing chamber 10, and configured to generate heat and heat the substrate W placed on the electrostatic chuck 112 by an electric power supplied from the heater power supply 70. As for the heater 71, for example, a plurality of resistive heaters is used, which may heat a plurality of regions of the electrostatic chuck 112 individually. The temperature sensor 72 is, for example, a thermocouple, and is provided at one or more positions in the electrostatic chuck 112. The temperature sensor 72 measures the temperature of an installation location in a time-series manner, and outputs temperature time-series data to the control unit 1b.

As for a material for the adhesive layer 110, an adhesive with a high thermal conductivity may be used. When focusing on the function of the lower electrode 111 as the cooling base, the adhesive layer 110 functions as a cooling layer interposed between the lower electrode 111 (cooling base) and the electrostatic chuck 112 (substrate placement stage). Further, an adhesive with a high electrical resistance may be used as the material of the adhesive layer 110, and the adhesive layer 110 may have a function to electrically insulate the lower electrode 111 and the electrostatic chuck 112 from each other. As the adhesive with the high thermal conductivity and the high electrical resistance, for example, an organic-based adhesive including a silicon-based material, an acrylic- or acrylate-based material, or a polyimide silica-based material may be used.

The control unit 1b of the plasma processing apparatus 1a controls the chiller unit 60 and the heater power supply 70 based on the temperature of the electrostatic chuck 112 measured by the temperature sensor 72. That is, the control unit 1b performs a temperature adjustment such that the temperature of the electrostatic chuck 112 reaches a target temperature, by controlling the temperature and the flow rate of the coolant supplied by the chiller unit 60, and further, controlling the magnitude of the power supplied by the heater power supply 70 to the heater 71.

It is desirable that during a plasma processing, the surface temperature of the electrostatic chuck 112 is uniform over the entire surface area of the electrostatic chuck 112. However, in addition to the heater 71 and the temperature sensor 72 described above, various mechanisms are provided in the electrostatic chuck 112, such as a plurality of lift pins that lifts a processed substrate W to a required height. Due to the mechanical structure of the electrostatic chuck 112, local spots that become hot or cold (hereinafter, referred to as singular spots) appear across the surface of the electrostatic chuck 112. The appearance of singular spots causes deviations in the distribution of the surface temperature of the electrostatic chuck 112. The deviations in the distribution of the surface temperature of the electrostatic chuck 112 result in the degradation of uniformity when the substrate W is processed.

When the distribution of the surface temperature of the electrostatic chuck 112 is estimated through a simulation using a physical model for the purpose of analyzing the cause of uniformity degradation, parameters are required such as the heat input to the electrostatic chuck 112 and the thermal conductivity between the electrostatic chuck 112 and the lower electrode 111. However, due to the complicated structure of the electrostatic chuck 112 as described above, it is difficult to accurately estimate the parameters.

The present embodiment proposes a method of estimating parameters of a physical model, including the heat input and the thermal resistance, by using temperature time-series data obtained as measured values during the temperature rise of the electrostatic chuck 112 and temperature transition data calculated using the physical model.

The physical model for estimating the temperature transition of the electrostatic chuck 112 is represented by, for example, Equation 1.

$$ρ c A Δ {z}_{c e r} \frac{\partial u}{\partial t} = {Q}_{IN} - {Q}_{o u t} \qquad < Equation 1 >$$

Here, “ρ” represents the density (g/m³) of the electrostatic chuck 112, “c” represents the specific heat (J/g·K) of the electrostatic chuck 112, “A” represents the heat flux passage cross-sectional area (m²), “ΔZ_{cer}” represents the thickness of the electrostatic chuck 112, “u” represents the temperature (K) of the electrostatic chuck 112, and “t” represents time(s). Q_{IN} represents heat input (W) to the electrostatic chuck 112, and Q_{OUT} represents heat output (W) from the electrostatic chuck 112 to the lower electrode 111. The heat output Q_{OUT} may be described using a temperature difference between the lower electrode 111 and the electrostatic chuck 112, and the thermal resistance Rₜₕ (mK/W) of the adhesive layer 110.

FIG. 3 is a graph illustrating a variation in temperature of the electrostatic chuck 112 over time. In the graph, the horizontal axis represents time(s), and the vertical axis represents the temperature (° C.) of the electrostatic chuck 112. The solid line temperature rise curve represents actual measured values, and the dashed line temperature rise curve represents values calculated by the physical model. The temperature rise curve of the actual measured values is obtained by, for example, measuring the temperature of the electrostatic chuck 112 in a time-series manner using the temperature sensor 72 while heating the electrostatic chuck 112 by the heater 71 and increasing the temperature of the electrostatic chuck 112 from a temperature around room temperature to a target temperature (350° C. in the example of FIG. 3). Instead of the heating by the heater 71, a plasma may be generated in the plasma processing chamber 10, and the temperature of the electrostatic chuck 112 may be increased using the state where the plasma is generated. While increasing the temperature of the electrostatic chuck 112, not only heat is input from the heater 71 (or plasma) to the electrostatic chuck 112, but also heat is output from the electrostatic chuck 112 to the lower electrode 111.

The temperature rise curve using the physical model is obtained by setting the parameters of the physical model to appropriate values, and calculating the temperature (u) at each time according to the physical model. As the parameters of the physical model, the heat input (=Q_{IN}) to the electrostatic chuck 112 and the thermal resistance Rₜₕ (or thermal conductivity “k” of a reciprocal thereof) related to the heat output Q_{OUT} may be used.

In the example of FIG. 3, a discrepancy occurs between the temperature rise curve obtained by the actual measurement and the temperature rise curve obtained from the physical model, which requires modifications in the parameters of the physical model.

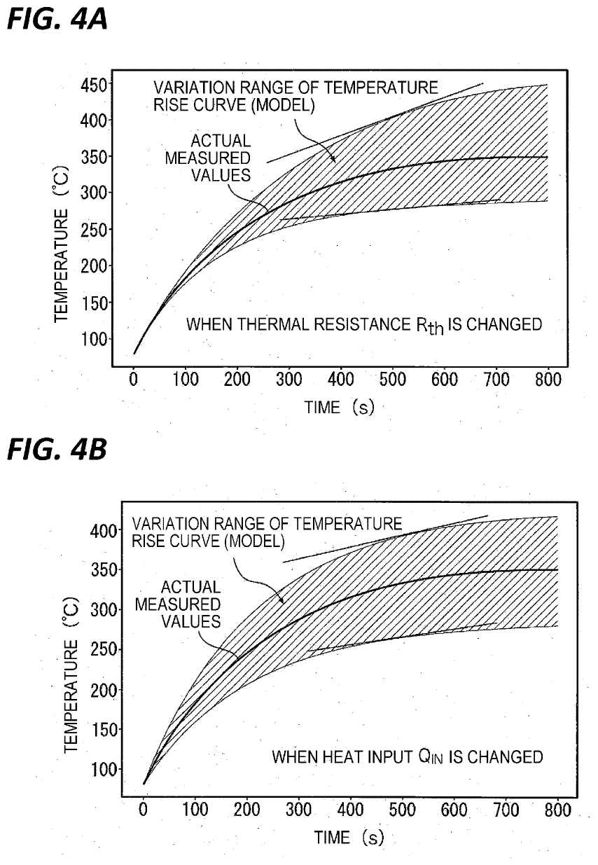

FIGS. 4A and 4B are graphs illustrating a variation in temperature rise curve when the parameters are changed. In the graph, the horizontal axis represents time(s), and the vertical axis represents the temperature (° C.) of the electrostatic chuck 112. FIG. 4A represents the range of the variation of the temperature rise curve when the value of the thermal resistance Rₜₕ is changed. When the value of the thermal resistance Rₜₕ in the physical model of Equation 1 is variously changed, the temperature rise curve obtained from the physical model varies in the range indicated by a hatching in FIG. 4A. As seen from the graph of FIG. 4A, even when the value of the thermal resistance Rₜₕ is changed, the temperature rise rate of a low temperature region (e.g., lower than 200° C.) hardly varies and is substantially constant. Meanwhile, it may be seen that the temperature rise rate of a high temperature region (e.g., equal to or higher than 250° C.) varies according to the value of the thermal resistance Rₜₕ, and the thermal resistance Rₜₕ contributes to the time required until the temperature “u” reaches a saturation temperature.

FIG. 4B represents the range of the variation of the temperature rise curve when the value of the heat input Q_{IN} is changed. When the value of the heat input Q_{IN} in the physical model of Equation 1 is variously changed, the temperature rise curve obtained from the physical model varies in the range indicated by a hatching in FIG. 4B. As seen from the graph of FIG. 4B, even when the value of the heat input Q_{IN} is changed, the time required until the temperature “u” of the electrostatic chuck 112 reaches the saturation temperature is substantially constant. Meanwhile, it may be seen that the temperature rise rate of the low temperature region (e.g., lower than 200° C.) varies according to the value of the heat input Q_{IN}.

As described above, the temperature rise rate of the high temperature region may be changed by changing the value of the thermal resistance Rₜₕ in the physical model, and the temperature rise rate of the low temperature region may be changed by changing the value of the heat input Q_{IN}. That is, it may be understood that it is difficult to reproduce the temperature rise curve of the actual measured values even by changing either of the thermal resistance Rₜₕ and the heat input Q_{IN}, but it is possible to make the temperature rise curve obtained from the physical model closer to the temperature rise curve of the actual measured values by changing both the parameters simultaneously.

Thus, the present embodiment calculates an error between the temperature time-series data obtained as the actual measured values and the temperature transition data calculated using the physical model, and determines the parameters (the thermal resistance Rₜₕ and the heat input Q_{IN}) in the physical model to minimize the calculated error.

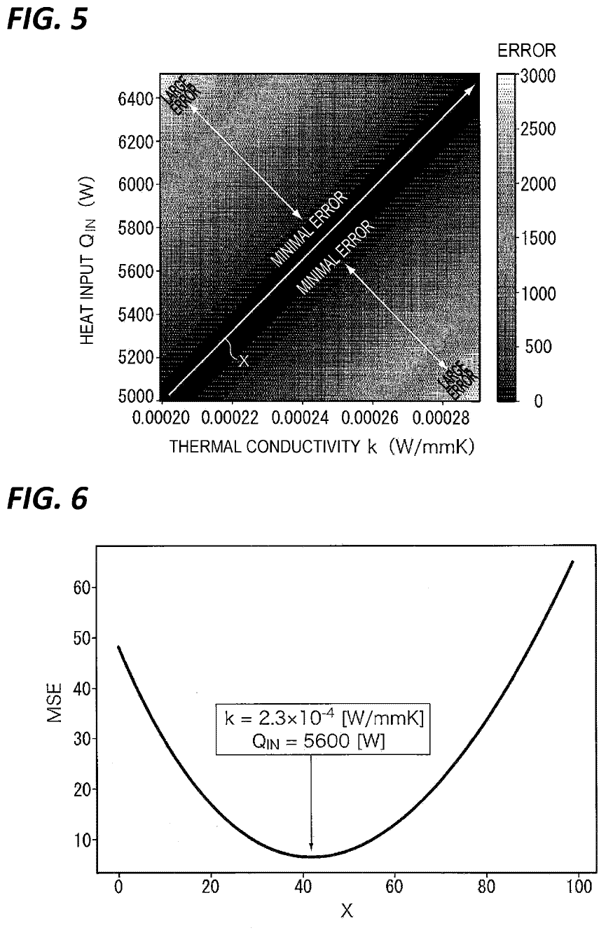

FIG. 5 is a graph illustrating an error distribution when the parameters are changed. In the graph, the horizontal axis represents the thermal conductivity “k” (W/mmK) of the adhesive layer 110, and the vertical axis represents the heat input Q_{IN} (W) to the electrostatic chuck 112. The thermal conductivity “k” is the reciprocal of the thermal resistance Rₜₕ. The shades of the graph represent the magnitude of a time-series error between the temperature time-series data obtained as the actual measured values and the temperature transition data calculated using the physical model. As the time-series error, for example, the mean square error (MSE) is used. When the value of the temperature time-series data at time “i” is Yᵢ, and the value of the temperature transition data at the time “i” is yᵢ, the mean square error is calculated by Σ(Yᵢ−yᵢ)²/n. Here, “n” represents the total number of data.

From the graph of FIG. 5, it may be identified that the magnitude of the error is relatively large in the upper left region and the lower right region of the graph, decreases from the upper left region and the lower right region toward the region near the center, and is minimal in the region along the diagonal line indicated by the white arrow “X.” Upon analyzing the magnitude of the error along the diagonal line, the distribution represented in FIG. 6 is obtained.

FIG. 6 is a graph illustrating the error distribution in the diagonal direction. In the graph, the horizontal axis represents points on the diagonal line indicated by the white arrow “X” in FIG. 5, and the vertical axis represents the magnitude of the error. Further, the horizontal axis represents rescaled coordinates where one end of the diagonal line is 0, and the other end thereof is 100.

As illustrated in FIG. 6, it may be identified that the magnitude of the error on the diagonal line is not constant, but is minimal at a specific point (the point where the thermal conductivity “k” is 2.3×10⁻⁴ (W/mmK), and the heat input Q_{IN} is 5,600 (W)).

That is, when calculating the error between the temperature time-series data obtained as the actual measured values and the temperature transition data calculated using the physical model, the values of the thermal resistance and the heat input that minimize the calculated error may be uniquely determined. Further, by using the values of the thermal resistance and the heat input that minimize the error as parameters, the physical model may be optimized.

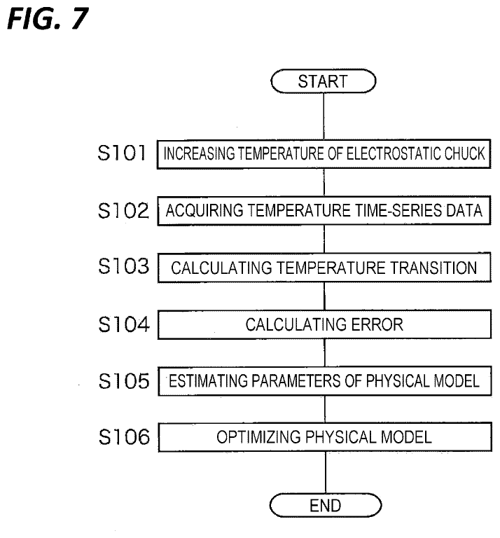

FIG. 7 is a flowchart illustrating a procedure of processes performed by the control unit 1b of the plasma processing system 1. The control unit 1b of the plasma processing system 1 increases the temperature of the electrostatic chuck 112 by controlling the operation of the plasma processing apparatus 1a (step S101). The control unit 1b may operate the heater power supply 70 and heat the electrostatic chuck 112 by the heater 71 to increase the temperature of the electrostatic chuck 112. Further, the control unit 1b may operate, for example, the RF power supply unit 30 and generate a plasma in the plasma processing chamber 10 to increase the temperature of the electrostatic chuck 112. The temperature of the electrostatic chuck 112 during the temperature rise is measured in the time-series manner by the temperature sensor 72.

The processing unit 511 acquires the temperature time-series data obtained by measuring the temperature of the electrostatic chuck 112 in the time-series manner during the temperature rise, through, for example, the communication interface 513 (step S102). The acquired temperature time-series data is stored in the storage unit 512.

The processing unit 511 calculates the temperature transition of the electrostatic chuck 112 by using the physical model represented in Equation 1 (step S103). It is assumed that the physical model or parameters (initial set values) used in the physical model are stored in the storage unit 512. The processing unit 511 may calculate the temperature transition of the electrostatic chuck 112 by reading the physical model or the parameters thereof from the storage unit 512, and performing arithmetic operations in accordance with the read physical model or parameters. The calculated temperature time-series data is stored in the storage unit 512.

In the present embodiment, the temperature time-series data by the actual measurement is acquired, followed by the calculation using the physical model. However, the procedure for performing the processes may be reversed, or the processes may be performed simultaneously in parallel.

The processing unit 511 calculates the error between the temperature time-series data acquired in step S102 and the temperature transition data calculated in step S103 (step S104). To this end, for example, the processing unit 511 may calculate the mean square error between the temperature time-series data obtained as the actual measured values and the temperature transition data calculated using the physical model.

Based on the calculated error, the processing unit 511 estimates the parameters of the physical model that include the heat input Q_{IN} to the electrostatic chuck 112 and the thermal resistance Rₜₕ (or thermal conductivity “k”) related to the heat output Q_{OUT} (step S105). Specifically, the processing unit 511 may determine the value of the heat input Q_{IN} and the value of the thermal resistance Rₜₕ (or thermal conductivity “k”) by using the finite difference time domain (FDTD) method, in order to minimize the error F

The processing unit 511 optimizes the physical model by updating the parameters (step S106). The processing unit 511 may optimize the physical model by storing the value of the heat input Q_{IN} and the value of the thermal resistance Rₜₕ (or thermal conductivity “k”) that have been determined in step S105, in the storage unit 512 as new parameters.

The flowchart of FIG. 7 represents the procedure in which the physical model is optimized according to the calculated error. However, the present disclosure may perform a procedure in which the physical model is optimized when the calculated error is greater than a threshold value, and is not optimized when the calculated error is less than the threshold value.

As described above, in the present embodiment, in the process of fitting the temperature transition data obtained from the physical model with the temperature time-series data obtained through the actual measurement, it is possible to estimate the parameters that may not be observed directly, such as the heat input Q_{IN} and the thermal resistance Rₜₕ. Further, since the estimation method of the present disclosure may be implemented when the temperature time-series data by the actual measurement is prepared, there are advantages in that an automatic estimation is possible during the execution of processes (e.g., a process designed for analytical purposes is unnecessary), and the user productivity is not affected.

In the present embodiment, the temperature of the electrostatic chuck 112 is measured using the temperature sensor 72 provided in the electrostatic chuck 112. However, as long as the temperature of the electrostatic chuck 112 may be measured in the time-series manner, the number or type of sensors provided is not limited. For example, the electrostatic chuck 112 may be provided with a plurality of temperature sensors 72 therein to measure the in-plane temperature distribution at each time, and each of the plurality of temperature sensors 72 may measure the temperature of the electrostatic chuck 112 in the time-series manner. In this case, the physical model may be prepared for each temperature sensor 72, and optimized based on the temperature time-series data obtained from each temperature sensor 72.

As the temperature sensor 72, an infrared camera may be used to capture images associated with the radiant heat emitted from the surface of the electrostatic chuck 112. The infrared camera is provided to face the surface of the electrostatic chuck 112, and outputs an image representing a surface temperature distribution of the electrostatic chuck 112 in a time-series manner. In this case, the temperature “u” included in the physical model is expressed as a function of time and location. The processing unit 511 may acquire time-series data (image data) of the surface temperature distribution from the infrared camera, calculate the surface temperature distribution at each time using the physical model, and estimate the parameters included in the physical model to minimize the error between the time-series data acquired from the infrared camera and the surface temperature distribution calculated at each time using the physical model.

In the present embodiment, the temperature time-series data during the temperature rise of the electrostatic chuck 112 is used. However, temperature time-series data during the temperature fall of the electrostatic chuck 112 may be used.

### Embodiment 2

In Embodiment 2, the operation of the plasma processing system 1 is described.

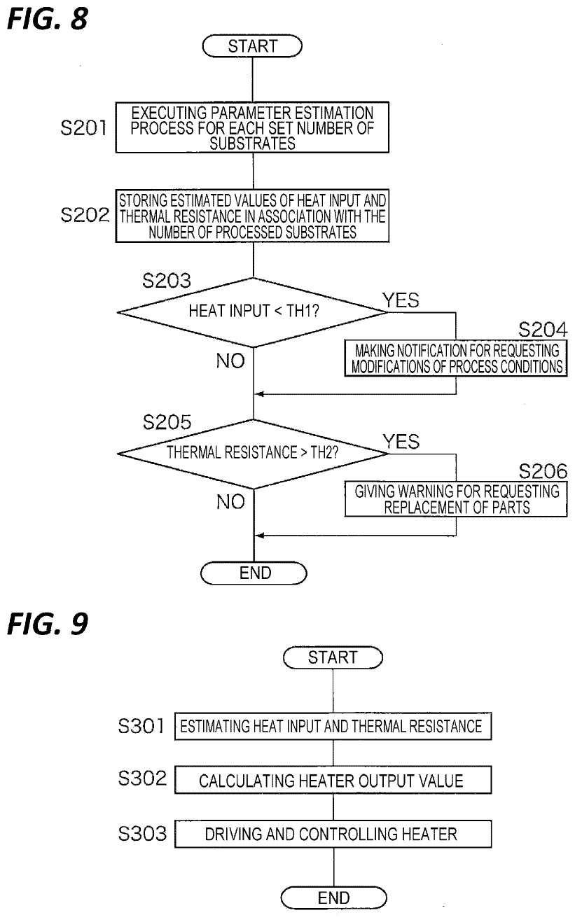

FIG. 8 is a flowchart illustrating a procedure of processes performed by the processing unit 511 according to Embodiment 2. The processing unit 511 performs a parameter estimation process each time a set number of substrates W are processed (step S201). The set number of substrates is set in advance. In an example, the set number of substrates is 500. Instead of the set number of substrates, the operation time of the plasma processing apparatus 1a may be used. The processing unit 511 performs the parameter estimation process according to the procedure of steps S101 to S105 represented in the flowchart of FIG. 7.

The processing unit 511 stores the parameters (i.e., the values of the heat input Q_{IN} and the thermal resistance Rₜₕ) estimated by the estimation process in the storage unit 512 in association with the total number of processed substrates (step S202).

The processing unit 511 determines whether the latest estimated value of the heat input Q_{IN} is less than a first threshold value TH1 (step S203). When the surface temperature distribution of the electrostatic chuck 112 is used as the temperature time-series data, the in-plane distribution of the heat input Q_{IN} may be monitored, and the uniformity of the plasma density may be evaluated based on the in-plane distribution of the heat input Q_{IN}.

When it is determined that the latest estimated value of the heat input Q_{IN} is less than the first threshold value TH1 (S203: YES), the processing unit 511 may determine that there a possibility the plasma density has become non-uniform, and therefore, makes a notification to request modifications of process conditions (step S204). For example, the processing unit 511 transmits a notification requesting modifications of process conditions, to a portable terminal of a user through the communication interface 513. Alternatively, the processing unit 511 may display information requesting modifications of process condition on a display unit (not illustrated).

When it is determined that the latest estimated value of the heat input Q_{IN} is equal to or more than the first threshold value TH1 (S203: NO), or when the notification requesting modifications of process conditions is made in step S204, the processing unit 511 determines whether the latest estimated value of the thermal resistance Rₜₕ is more than a second threshold value TH2 (step S205). By monitoring the value of the thermal resistance Rₜₕ, the processing unit 511 may evaluate the degree of wear of the adhesive layer 110.

When it is determined that the latest estimated value of the thermal resistance Rₜₕ is more than the second threshold value TH2 (S205: YES), the processing unit 511 may determine that the electrostatic chuck 112 is deteriorating as wearing due to radicals or heat, and therefore, outputs a warning to request the replacement of parts (step S206). For example, the processing unit 511 transmits the warning requesting the replacement of parts to the portable terminal of the user through the communication interface 513. Alternatively, the processing unit 511 may display the warning requesting the replacement of parts on a display unit (not illustrated).

As described above, in Embodiment 2, the parameter estimation process is performed for each set number of substrates. By estimating the value of the heat input Q_{IN}, the processing unit 511 may monitor the uniformity of the plasma density, and request modifications of process conditions before the yield deteriorates. Further, by estimating the thermal resistance Rₜₕ, the processing unit 511 may monitor the degree of wear of the adhesive layer 110, and output the warning before the electrostatic chuck 112 reaches the end of its lifespan.

### Embodiment 3

In Embodiment 3, descriptions are made on a configuration in which a heater output value is calculated based on the values of the heat input Q_{IN} and the thermal resistance Rₜₕ estimated in the estimation process described above, to drive and control the heater 71.

FIG. 9 is a flowchart illustrating a procedure of processes performed by the processing unit 511 according to Embodiment 3. In a preparation process prior to the main process of processing substrates, the processing unit 511 estimates the values of the heat input Q_{IN} and the thermal resistance Rₜₕ in the same procedure as in Embodiment 1 (step S301). In the preparation process, in a state where dummy wafers are placed on the electrostatic chuck 112, and a plasma is generated, the temperature of the electrostatic chuck 112 is increased from room temperature to a target temperature. The target temperature is set to a process temperature in the present process. As in Embodiment 1, the processing unit 511 estimates the values of the heat input Q_{IN} and the thermal resistance Rₜₕ by fitting the temperature transition data obtained from the physical model with the temperature time-series data obtained through the actual measurement.

Based on the estimated values of the heat input Q_{IN} and the thermal resistance Rₜₕ, the processing unit 511 calculates a heater output value until the electrostatic chuck 112 reaches the target temperature from room temperature (step S302). The present step may be performed prior to the main process of processing the substrates W. When the values of the heat input Q_{IN} and the thermal resistance Rₜₕ, and the target temperature are given, the processing unit 511 calculates the heater output value using a conversion formula or table that has been pre-learned to output the heater output value until the electrostatic chuck 112 reaches the target temperature from room temperature. The heater output value may not be constant, but may vary moment by moment until the electrostatic chuck 112 reaches the target temperature from room temperature.

The processing unit 511 drives and controls the heater 71 based on the calculated heater output value (step S303). In the main process of processing substrates, the processing unit 511 drives and controls the heater 71 by controlling the output of the heater power supply 70 to become the heater output value calculated in step S302, with the control unit 1b.

As described above, in Embodiment 3, the drive/control of the heater 71 may be performed after checking the values of the heat input Q_{IN} and the thermal resistance Rₜₕ, so that, for example, the temperature may be prevented from overshooting at the start time of the process.

### Embodiment 4

In Embodiment 4, descriptions are made on a configuration to estimate the in-plane distribution of the heat input Q_{IN}, and adjust the amount of gas in the substrate plane according to the estimation result.

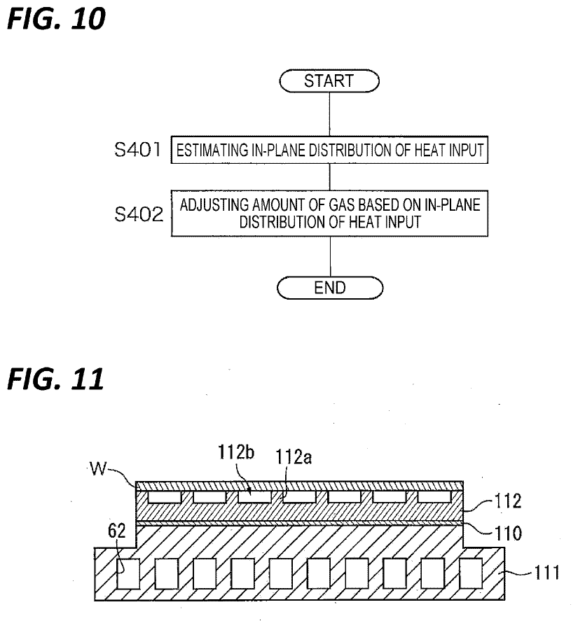

FIG. 10 is a flowchart illustrating a procedure of processes performed by the processing unit 511 according to Embodiment 4. In the preparation process prior to the main process of processing substrates, the processing unit 511 estimates the values of the heat input Q_{IN} and the thermal resistance Rₜₕ in the same procedure as in Embodiment 1. In the preparation process, in a state where dummy wafers are placed on the electrostatic chuck 112, and a plasma is generated, the temperature of the electrostatic chuck 112 is increased from room temperature to a target temperature. The target temperature is set to a process temperature in the present process. As in Embodiment 1, the processing unit 511 estimates the values of the heat input Q_{IN} and the thermal resistance Rₜₕ by adjusting the temperature transition data obtained from the physical model to the temperature time-series data by the actual measurement.

In Embodiment 4, the values of the heat input Q_{IN} and the thermal resistance Rₜₕ are estimated in each of a plurality of regions within the substrate plane, by using a plurality of temperature sensors 72 or an infrared camera as the temperature sensor 72. The processing unit 511 estimates the in-plane distribution of the heat input Q_{IN} based on the value of the heat input Q_{IN} in each region (step S401).

The processing unit 511 adjusts the amount of gas in each region based on the estimated in-plane distribution of the heat input Q_{IN} (step S402). In the main process of processing substrates, the processing unit 511 controls the operation of the gas supply unit 20 by the control unit 1b, and adjusts the amount of gas in each region of the substrate plane to achieve, for example, the plasma density that may produce an optimal etching shape.

As described above, in Embodiment 4, the amount of gas in each region of the substrate plane is adjusted according to the in-plane distribution of the heat input Q_{IN}, so the plasma density in each region may be controlled, and the etching shape may be optimized.

### Embodiment 5

In Embodiment 5, descriptions are made on a configuration in which the electrostatic chuck 112 includes protrusions.

FIG. 11 is a schematic view illustrating the configuration of the electrostatic chuck 112 according to Embodiment 5. The schematic view of FIG. 11 illustrates the adhesive layer 110, the lower electrode 111, and a substrate W, in addition to the electrostatic chuck 112. The configuration and the function of the adhesive layer 110 and the lower electrode 111 are the same as those in Embodiment 1.

In Embodiment 5, the electrostatic chuck 112 includes a plurality of protrusions 112a for placing the substrate W thereon. The substrate W to be processed is placed on the upper surfaces of the protrusions 112a. The protrusions 112a are formed of ceramics integrated with the body of the electrostatic chuck 112. A heat transfer gas such as He gas is supplied to voids 112b formed when the substrate W is placed on the upper surfaces of the protrusions 112a.

In Embodiment 5, the processing unit 511 estimates the value of the heat input Q_{IN} to the substrate W placed on the protrusions 112a and the value of the thermal resistance of the protrusions 112a in the same procedure as in Embodiment 1. That is, the processing unit 511 may estimate the values of the heat input Q_{IN} and the thermal resistance Rₜₕ in the process of adjusting the temperature transition data obtained from the physical model to the temperature time-series data obtained through the actual measurement. In Embodiment 5, a wafer-type temperature sensor may be used as the temperature sensor 72 to measure the temperature of each protrusion 112a.

Further, the processing unit 511 may apply the same procedure as in Embodiment 2 to compare the value of the thermal resistance Rₜₕ estimated for each protrusion 112a with a predetermined set value, and detect the wear of each protrusion 112a based on the comparison result. Further, when the wear of the protrusion 112a is detected in the main process of processing substrates or a temperature adjustment process where a plasma is not ignited, the processing unit 511 may output a warning to request the replacement of parts.

As described above, in Embodiment 5, it is possible to precisely estimate the value of the thermal resistance Rₜₕ of each protrusion 112a that may not be obtained individually.

According to the present disclosure, it is possible to estimate parameters in a physical model for calculating a temperature transition of a substrate placement stage.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A parameter estimation system comprising:
acquisition circuitry configured to acquire temperature time-series data obtained by measuring a temperature of a substrate placement stage provided in a substrate processing apparatus in a time-series manner when increasing the temperature of the substrate placement stage, the substrate processing apparatus including the substrate placement stage and a cooling base that adjusts the temperature of the substrate placement stage via a cooling layer;
model calculation circuitry configured to calculate a temperature transition of the substrate placement stage using a physical model;
error calculation circuitry configured to calculate an error between the temperature time-series data acquired by the acquisition circuitry and temperature transition data obtained from the model calculation circuitry; and
estimation circuitry configured to estimate parameters in the physical model, including a value of heat input to the substrate placement stage and a value of thermal resistance of the cooling layer, based on the error calculated by the error calculation circuitry.

2. The parameter estimation system according to claim 1, wherein the substrate placement stage is an electrostatic chuck that adsorbs a substrate when a DC voltage is applied.

3. The parameter estimation system according to claim 1, wherein the substrate placement stage is formed of ceramics.

4. The parameter estimation system according to claim 1, wherein the substrate placement stage is equipped with a temperature sensor.

5. The parameter estimation system according to claim 1, wherein the substrate placement stage includes a heater for temperature adjustment.

6. The parameter estimation system according to claim 5, wherein the substrate processing apparatus calculates a heater output value until the substrate placement stage reaches a set temperature based on the value of the heat input and the value of the thermal resistance that are estimated by the estimation circuitry, and drives and controls the heater based on the calculated heater output value.

7. The parameter estimation system according to claim 1, wherein in a preparation process prior to performing a main process of processing a substrate, the estimation circuitry estimates an in-plane distribution of the heat input to the substrate placement stage, and
according to the in-plane distribution of the heat input estimated by the estimation circuit, the substrate processing apparatus adjusts an amount of gas within a substrate plane, and performs the main process of processing the substrate.

8. The parameter estimation system according to claim 1, further comprising:
detection circuitry configured to compare the value of the thermal resistance estimated by the estimation circuitry with a set value for the thermal resistance, and detect a wear of the cooling layer based on a comparison result.

9. The parameter estimation system according to claim 8, further comprising:
output circuitry configured to output a warning to request a replacement of parts, when the detector detects the wear of the cooling layer, in the main process of processing the substrate or a temperature adjustment process in which a plasma is not ignited.

10. The parameter estimation system according to claim 1, wherein the estimating by the estimation circuitry are performed each time a set number of substrates are processed, and
the value of the heat input and the value of the thermal resistance that are estimated by the estimation circuitry are stored in a storage device in association with a number of processed substrates.

11. The parameter estimation system according to claim 1, wherein a protrusion is provided on the substrate placement stage to place a substrate thereon, and
the estimation circuitry estimates the value of the heat input to the substrate placed on the protrusion, and the thermal resistance of the protrusion.

12. The parameter estimation system according to claim 11, wherein a temperature of the substrate placement stage is measured by a wafer-type temperature sensor disposed in the protrusion.

13. The parameter estimation system according to claim 11, further comprising:
detection circuitry configured to compare the value of the thermal resistance estimated by the estimation circuitry with a set value for the thermal resistance, and detect a wear of the protrusion based on a comparison result.

14. The parameter estimation system according to claim 13, further comprising:
output circuitry configured to output a warning to request a replacement of parts, when the detector detects the wear of the protrusion, in the main process of processing the substrate or a temperature adjustment process in which a plasma is not ignited.

15. The parameter estimation system according to claim 1, wherein the estimation circuitry estimates the parameters in the physical model to minimize the error.

16. A parameter estimation method comprising:
acquiring, by a processor, temperature time-series data obtained by measuring a temperature of a substrate placement stage provided in a substrate processing apparatus in a time-series manner when increasing the temperature of the substrate placement stage, the substrate processing apparatus including the substrate placement stage and a cooling base that adjusts the temperature of the substrate placement stage via a cooling layer,
calculating, by the processor, a temperature transition of the substrate placement stage using a physical model,
calculating, by the processor, an error between the temperature time-series data acquired in the acquiring of the temperature time-series data and temperature transition data obtained from the physical model, and
estimating, by the processor, parameters in the physical model, including a value of heat input to the substrate placement stage and a value of thermal resistance of the cooling layer, based on the error calculated in the calculating of the error.

17. A non-transitory computer-readable storage medium having stored therein a program, which causes a computer to execute a process including:
acquiring temperature time-series data obtained by measuring a temperature of a substrate placement stage provided in a substrate processing apparatus in a time-series manner when increasing the temperature of the substrate placement stage, the substrate processing apparatus including the substrate placement stage and a cooling base that adjusts the temperature of the substrate placement stage via a cooling layer, calculating a temperature transition of the substrate placement stage using a physical model,
calculating an error between the temperature time-series data acquired in the acquiring of the temperature time-series data and temperature transition data obtained from the physical model, and
estimating parameters in the physical model, including a value of heat input to the substrate placement stage and a value of thermal resistance of the cooling layer, based on the error calculated in the calculating of the error.

18. A substrate processing apparatus comprising:
the parameter estimation system according to claim 1.
